(19) United States
(12) Patent Application Publication
(10) Pub. No.: US 2010/0136767 A1
(43) Pub. Date: Jun. 3, 2010

(54) METHOD FOR PRODUCTION OF THIN FILM AND APPARATUS FOR MANUFACTURING THE SAME

(75) Inventors: Nong Moon Hwang, Seoul (KR); Yung Bin Chung, Gangneung-si (KR); Dong Kwon Lee, Seoul (KR)

Correspondence Address: Jae Y. Park, Kile, Goekjian, Reed & McManus, PLLC, 1200 New Hampshire Ave. NW, Suite 570, Washington, DC, 20036, US

(73) Assignee: SNU R&DB FOUNDATION, Seoul (KR)

(21) Appl. No.: 12/531,436

(22) PCT Filed: Aug. 19, 2008
(86) PCT No.: PCT/KR2008/004795

§ 371 Date: Sep. 15, 2009

(30) Foreign Application Priority Data
Aug. 20, 2007 (KR) 10-2007-0083529
Aug. 6, 2008 (KR) 10-2008-0076777

(51) Int. Cl. H01L 21/326; B05B 5/00

(52) U.S. Cl. 438/468; 118/620; 257/E21.327; 977/742; 977/762; 977/773

(57) ABSTRACT

A method for manufacturing a thin film is provided. A substrate is loaded into a chamber. A first reaction gas and a second reaction gas are supplied into the chamber. The first reaction gas is dissociated to form crystalline nanoparticles. An amorphous material is inhibited from being formed on the substrate using the second reaction gas. Thereafter, a crystalline thin film is formed from the crystalline nanoparticles provided on the substrate.

### TECHNICAL FIELD

The present disclosure relates to a method and apparatus for manufacturing a thin film, and more particularly, to a method and apparatus for manufacturing a crystalline thin film using crystalline nanoparticles.

### BACKGROUND ART

Conventionally, to obtain a crystallized silicon film, an amorphous silicon (a-Si) film is deposited on a substrate using a chemical vapor deposition (CVD) process, such as a plasma-enhanced CVD (PECVD) process or a hot-filament CVD (HFCVD) process (or a hot-wire CVD (HWCVD) process), and then recrystallized at a high temperature for a long duration of time using a solid phase crystallization (SPC) process, a metal induced lateral crystallization (MILC) process, or an excimer laser annealing (ELA) crystallization process. Alternatively, the surface of the deposited a-Si film is instantaneously crystallized using a catalyst or an excimer laser.

As described above, the crystallization of an a-Si film involves two process steps (i.e., a film deposition process and a crystallization process), thereby complicating the entire process. Specifically, since an annealing process is performed over a lengthy period of time, process speed can be slowed. Also, a substrate formed of a heat-resistant material is required to perform the annealing process at a high temperature over a lengthy period of time. In addition, when an a-Si film is crystallized using a catalyst, impurities may remain on the deposited a-Si film. Furthermore, crystallization of an a-Si film using an excimer laser needs a high-priced laser system.

### DISCLOSURE

### Technical Problem

The present disclosure is directed to a method of manufacturing a thin film capable of depositing a high-quality crystalline thin film without an additional post-annealing process or a dehydrogenation process.

Also, the present disclosure is directed to an apparatus for manufacturing a thin film capable of depositing a high-quality crystalline thin film without an additional post-annealing process or a dehydrogenation process.

### Technical Solution

One aspect of the present disclosure provides a method of manufacturing a thin film. In the method, a substrate is first loaded into a chamber. A first reaction gas and a second reaction gas are supplied into the chamber. The first reaction gas is dissociated to form crystalline nanoparticles. An amorphous material is inhibited from being formed on the substrate using the second reaction gas. Thereafter, a crystalline thin film is formed from the crystalline nanoparticles provided on the substrate.

According to an example embodiment, the crystalline nanoparticles may be negative-charged or positive-charged depending on the type of the crystalline nanoparticles.

According to another example embodiment, an electric field may be generated in the substrate to guide the charged crystalline nanoparticles to the substrate.

According to still another example embodiment, the amorphous material may be inhibited from growing on the substrate using the second reaction gas or an already grown amorphous material may be etched using the second reaction gas.

According to yet another example embodiment, the crystallinity of the crystalline thin film may be determined by a mixture ratio of the first reaction gas and the second reaction gas that are supplied.

Another aspect of the present disclosure provides an apparatus for manufacturing a thin film. The apparatus includes: a chamber into which a substrate is loaded; a first gas supplier configured to supply a first reaction gas into the chamber; an energy source configured to dissociate the first reaction gas to form crystalline nanoparticles; and a second gas supplier configured to supply a second reaction gas used to inhibit an amorphous material from being formed on the substrate.

According to an example embodiment, the energy source may be a hot-wire structure installed between the first gas supplier and the substrate.

According to another example embodiment, the apparatus may further include a substrate shield installed over the substrate to be capable of being opened and closed and configured to shield the substrate from the first reaction gas or heat emitted by the energy source.

According to still another example embodiment, the apparatus may further include a bias applier connected to the substrate and configured to generate an electric field in the substrate.

### Advantageous Effects

According to some example embodiments of the present disclosure, a high-quality crystalline thin film can be deposited without an additional post-annealing process or dehydrogenation process. By omitting the post-annealing process or the dehydrogenation process, a process time and production costs can be reduced. Since a reaction gas is dissociated due to a hot-wire structure spaced apart from a substrate, a low-temperature process can be performed on the substrate. Accordingly, various kinds of substrates can be employed irrespective of a process temperature.

Furthermore, according to some example embodiments of the present disclosure, the crystallinity of a thin film can be controlled according to a ratio of reaction gases.

### DESCRIPTION OF DRAWINGS

FIG. 1 is a schematic view of a thin film deposition apparatus according to a first example embodiment of the present disclosure.

FIG. 2 is a schematic view of a thin film deposition apparatus according to a second example embodiment of the present disclosure.

FIG. 3 is a schematic view of a thin film deposition apparatus according to a third example embodiment of the present disclosure.

FIG. 4 is a conceptual diagram of a thin film deposition mechanism according to an example embodiment of the present disclosure.

FIG. 5 is a flowchart illustrating a method of manufacturing a thin film according to an example embodiment of the present disclosure.

FIG. 6 is a graph of simulation results showing supersaturation of silicon (Si) in a Cl-containing atmosphere.

FIG. 7 is a graph of measurement results of the thin films deposited according to the flow rate of HCl, which are obtained using a Raman spectrometer, according to an example embodiment of the present disclosure.

### MODE FOR INVENTION

Hereinafter, example embodiments of the present disclosure will be described in detail. However, the scope of the present disclosure is not limited to the example embodiments disclosed below, but can be implemented in various other types. Therefore, the present example embodiments are provided for complete disclosure of the present disclosure and to fully inform the scope of the present disclosure to those ordinarily skilled in the art. In the drawings, the widths or thicknesses of layers (or films) and regions are exaggerated for clarity. The drawings are generally described from the viewpoint of an observer. It will also be understood that when a film is referred to as being “on” another film or substrate, it can be directly on the other film or substrate or intervening films may also be present. The same reference numerals are used to denote the same elements throughout the specification.

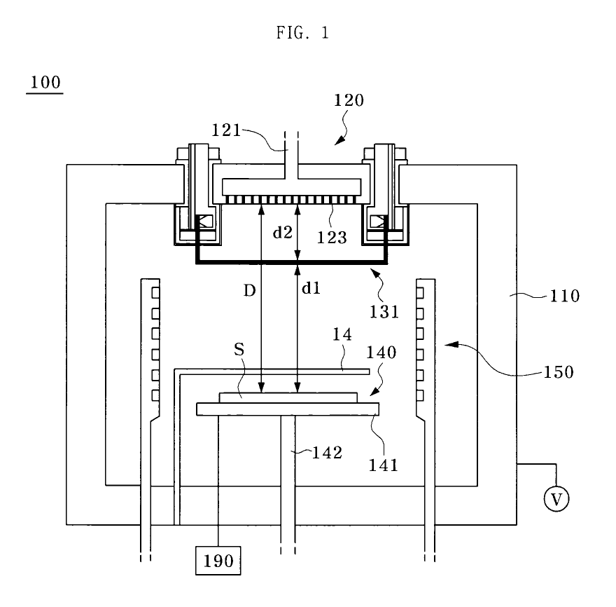

FIG. 1 is a schematic view of a thin film deposition apparatus according to a first example embodiment of the present disclosure.

Referring to FIG. 1, a thin film deposition apparatus 100 according to the present example embodiment includes a chamber 110 into which a substrate S is loaded, a first gas supplier 120 for supplying a first reaction gas into the chamber 110, an energy source 131 for dissociating the first reaction gas to form crystalline nanoparticles, and a second gas supplier 150 for supplying a second reaction gas to inhibit an amorphous material from being formed on the substrate S. The thin film deposition apparatus 100 may further include a substrate support 140 for supporting the substrate S, a bias applier 190 for generating an electric field in the substrate S, and a substrate shield 14 installed over the substrate S to be capable of being opened and closed.

The chamber 110 may communicate with a vacuum pumping system V and include a substrate door (not shown) through which the substrate S may be loaded and unloaded.

The first gas supplier 120 may be disposed in an upper portion of the chamber 110. As shown, in the present example embodiment, the first gas supplier 120 may be a shower head 120. The shower head 120 may be disposed in the upper portion of the chamber 110 and supply the first reaction gas into the chamber 110. The shower head 120 may include a gas inlet port 121 and a gas injection hole 123.

The first reaction gas may be externally supplied through the gas inlet port 121 to the shower head 120 and supplied into the chamber 110 through the gas injection hole 123.

According to an example embodiment, the first reaction gas may contain an element of a thin film that is substantially formed on the substrate S.

According to an example embodiment, when a Si thin film is formed, the first reaction gas may include a silane-based compound denoted by SiₙH₂ₙ₊₂ (here, n is a natural number). For example, the first reaction gas may contain monosilane, disilane, trisilane, or tetrasilane. Specifically, the first reaction gas may contain monosilane, disilane, trisilane, or a gas mixture thereof. According to another example embodiment, the first reaction gas may include fluorosilane, an organic silane, or a compound or mixture thereof. The fluorosilane may be denoted by SiₙH₂ₙ₊₂₋ₘFₘ (here, each of n and m is a natural number, m<2n+2, and m may include 0), and may include SiH₃F, SiH₂F₂, SiHF₃, SiF₄, Si₂F₆, Si₂HF₅, Si₃F₈. The organic silane may be denoted by SiₙR₂ₙ₊₂₋ₘH, and may include Si(CH₃)H₃, Si(CH₃)₂H₂, or Si(CH₃)₃H.

According to another example embodiment, when a germanium (Ge) thin film is formed, the first reaction gas may be a Ge gas, a germanium fluoride gas, or a compound or mixture thereof. In the specification, the Ge gas indicates a gas that may be denoted by GeₙHe₂ₙ₊₂. The Ge gas, for example, may include GeH₄ or Ge₂H₆. The germanium fluoride gas may be denoted by GeₙH₂ₙ₊₂₋ₘFₘ and may include GeF₄.

According to still another example embodiment, when a carbon thin film, a carbon nanotube, or a carbon nanowire is deposited, the first reaction gas may include a hydrocarbon gas or other hydrocarbon compounds. The hydrocarbon gas may be, for example, CH₄, C₂H₆, C₃H₈, C₂H₄, or C₂H₂.

According to yet another example embodiment, although each of the above-described examples of the first reaction gas may be used alone, an additional gas may be used along with the first reaction gas. The additional gas may be: a reactive gas, such as a fluorine (F) gas or a chlorine (Cl) gas; a gas containing a Group III element as a dopant, such as B₂H₆ or B(CH₃)₃; a gas containing a Group V element as a dopant, such as PH₃; an inert gas, such as He gas, Ar gas, or Ne gas; or hydrogen (H₂) gas or nitrogen (N₂) gas. The additional gas may be mixed with the first reaction gas and supplied through the shower head 120. Alternatively, the additional gas may be separated from the first reaction gas and supplied to the chamber 110 through an additional gas supplier (not shown).

According to an example embodiment, the first reaction gas may be supplied in a gaseous phase or in a vapor phase vaporized from liquid into the chamber 110. When the first reaction gas is supplied in the vapor phase vaporized from liquid, a carrier gas for carrying the vapor into the chamber 110 may be additionally used. The carrier gas may be a nonreactive gas, for example, H₂ gas, N₂ gas, He gas, or Ar gas.

The energy source 131 may be disposed under the shower head 120. According to the first example embodiment, the energy source 131 may be a hot-wire structure 131. The hot-wire structure 131 may be formed of a metal, such as tungsten (W), and have a lattice shape or a filament shape. When a current is supplied to the hot-wire structure 131, the hot-wire structure 131 may generate heat due to electrical resistance. The heat generated by the hot-wire structure 131 may chemically dissociate the first reaction gas supplied through the shower head 120. The hot-wire structure 131 may be controlled to generate such sufficient heat as to dissociate combinations between elements of the first reaction gas.

According to an example embodiment, when the first reaction gas contains an element of a thin film that is substantially formed on the substrate S, the hot-wire structure 131 may dissociate the first reaction gas to form the crystalline nanoparticles.

The substrate S may be disposed on the substrate support 140. The substrate S may be formed of a conductive material, a nonconductive material, or a polymer. For example, the substrate S may be a metal substrate, a polymer substrate, or a metal oxide substrate.

The substrate support 140 may be disposed in a lower portion of the chamber 110 to face the shower head 120. As shown, the substrate support 140 may include a seat 141 for supporting the substrate S and a support portion 142 for rotating the substrate S or moving the substrate S up and down. Although not shown in the drawings, the substrate support 140 may further include a heater for heating the substrate S mounted on the seat 141, a thermocouple for measuring the temperature of the substrate S or the seat 141, and a cooler for cooling the heater.

The substrate shield 14 may be disposed on the substrate support 140. The substrate shield 14 may be capable of being placed on or withdrawn from the substrate S through rotational or translational motion. Also, the substrate shield 14 may be capable of being opened and closed such that the substrate S is not exposed to the shower head 120 or the hot-wire structure 131, thereby shielding the substrate S from gases supplied from the shower head 120 or heat emitted from the hot-wire structure 131. Accordingly, the substrate shield 14 may selectively allow or cut off the flow of the first reaction gas supplied from the shower head 120 onto the substrate S. In addition, the substrate shield 14 may selectively allow or cut off the application of heat emitted by the hot-wire structure 131 to the substrate S. By use of the substrate shield 14, the thickness of a thin film to be deposited on the substrate S may be controlled, and a part of the first reaction gas, which does not reach a normal state in an initial stage of a deposition process, may be prevented from being deposited on the substrate S. The substrate shield 14 may be provided to be movable up and down, thereby controlling the height of the substrate shield 14. Owing to a vertically movable structure of the substrate support 140, not only a distance D between the substrate S and the shower head 120 but also a distance d1 between the substrate S and the hot-wire structure 131 may be controlled. In order to control a distance d2 between the shower head 120 and the hot-wire structure 131, the shower head 120 or the hot-wire structure 131 may be configured to be movable up and down. The distances d1, d2, and D may be changed depending on the internal pressure of the chamber 110 and controlled according to heat capacity transmitted to the substrate S or the deposition rate of a thin film.

The bias applier 190 may be disposed under the chamber 110. The bias applier 190 may apply a bias voltage to the substrate S mounted on the seat 141 to generate an electric field in the substrate S. According to an example embodiment, when the crystalline nanoparticles formed by dissociating the first reaction gas are charged inside the chamber 110, the electric field generated in the substrate S may guide the charged crystalline nanoparticles toward the substrate S. In this case, the charged crystalline nanoparticles may reach the substrate S at a relatively high flux. As a result, adhesion of a thin film formed from the charged crystalline nanoparticles to the substrate S may be improved, and the deposition rate of the thin film may be increased. Furthermore, the crystallinity of the deposited thin film may be increased.

The second gas supplier 150 may be disposed in the chamber 110. The second gas supplier 150 may externally receive the second reaction gas and supply the second reaction gas on the substrate S. According to an example embodiment, the second gas supplier 150 may be disposed to supply the second reaction gas to the space having a distance of d1 in the chamber 110. According to an example embodiment, the second reaction gas may supply the second reaction gas in a gaseous phase or a vapor phase into the chamber 110. The vapor-phase second reaction gas may be obtained by evaporating a liquid source. According to an example embodiment, the second reaction gas may act on the substrate S to inhibit formation of an amorphous material from the vapor-phase first reaction gas on the substrate S during formation of a crystalline thin film. The second reaction gas may include a compound gas containing a Group 17 element, such as hydrogen chloride (HCl). The second reaction gas may include a highly reactive element, such as a chloride-based gas or a fluoride-based gas.

According to an example embodiment, although each of the above-described examples of the second reaction gas may be used alone, an additional gas may be used along with the second reaction gas. The additional gas may be: a gas containing a Group III element as a dopant, such as B₂H₆ and B(CH₃)₃; a gas containing a Group V element as a dopant, such as PH₃; an inert gas, such as He gas, Ar gas, or Ne gas; or H₂ gas or N₂ gas. The additional gas may be mixed with the second reaction gas and supplied through the second gas supplier 150. Alternatively, the additional gas may be separated from the second reaction gas and supplied to the chamber 110 through an additional gas supplier (not shown).

According to an example embodiment, when the second reaction gas is supplied in a vapor phase, a carrier gas for carrying the vapor into the chamber 110 may be additionally used. The carrier gas may be a nonreactive gas, for example, H₂ gas, N₂ gas, He gas, or Ar gas.

In the above-described thin film deposition apparatus 100, it is exemplarily described that the first reaction gas may be supplied through the shower head 120 into the chamber 110, and the second reaction gas may be supplied through the second gas supplier 150 into the chamber 110, but the scope of the present disclosure is not limited thereto. For example, the first reaction gas or the second reaction gas may be supplied through the shower head 120 or the second gas supplier 150 into the chamber 110.

In the thin film deposition apparatus 100 according to the present embodiment, the first reaction gas supplied from the shower head 120 may be dissociated by the hot-wire structure 131 in the chamber 110 to form crystalline nanoparticles. The crystalline nanoparticles may be positive-charged or negative-charged according to the types of the crystalline nanoparticles in the chamber 110 and then guided onto the substrate S along the electric field generated by the bias applier 190, thereby forming a crystalline thin film on the substrate S. The second reaction gas supplied from the second gas supplier 150 may prevent an amorphous material from being formed on the substrate S during formation of the crystalline thin film. As explained above, the first reaction gas containing an element of a thin film to be formed may be dissociated in a vapor phase beforehand to form the crystalline nanoparticles, so that the crystalline thin film can be formed from the crystalline nanoparticles provided on the substrate S at a low temperature. Accordingly, various kinds of substrates, such as a glass substrate or a polymer substrate, may be employed. In addition, since the second reaction gas may inhibit formation of an amorphous material from the first reaction gas on the substrate S, the crystallinity of the deposited crystalline thin film may be increased.

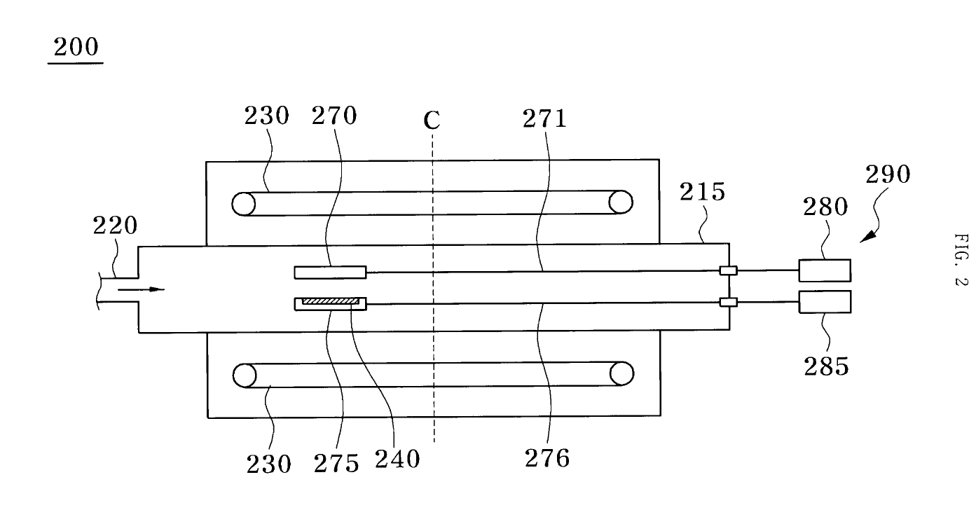

FIG. 2 is a schematic view of a thin film deposition apparatus according to a second example embodiment of the present disclosure.

Referring to FIG. 2, a thin film deposition apparatus 200 according to the second example embodiment of the present disclosure may include a chamber 215 into which a substrate 240 is loaded, a gas supplier 220, and an energy source 230. The thin film deposition apparatus 200 may further include a bias applier 290 for generating an electric field in the substrate 240.

As shown, the thin film deposition apparatus 200 may be provided in the form of a horizontal furnace, and a gas may be horizontally supplied to and exhausted from the chamber 215. The chamber 215 may have a tube shape and be formed of quartz.

The gas supplier 220 may supply a first reaction gas or a second reaction gas into the chamber 215. According to an example embodiment of the present disclosure, the gas supplier 220 may supply the first reaction gas and the second reaction gas through an additional pipeline into the chamber 215. According to another example embodiment, the gas supplier 220 may mix the first reaction gas with the second reaction gas and supply the gas mixture through a single pipeline into the chamber 215. According to an example embodiment, the first reaction gas may include an element of a thin film that is substantially formed on the substrate 240. According to an example embodiment, the second reaction gas may act on the substrate 240 to inhibit formation of an amorphous material on the substrate 240 during formation of a crystalline thin film. According to an example embodiment, the first reaction gas or the second reaction gas may be supplied in a gaseous phase or a vapor phase into the chamber 215. In this case, the vapor-phase first reaction gas or second reaction gas may be obtained by evaporating a liquid source.

The energy source 230 may be disposed around the substrate 240. According to the second example embodiment, the energy source 230 may be a heating unit 230. The heating unit 230 may be formed of graphite or Si and provided in the shape of a pipe, a plate, or a coil.

According to an example embodiment, the heating unit 230 may emit heat and dissociate the first reaction gas including an element of a thin film that is substantially formed on the substrate 240, thereby forming crystalline nanoparticles.

The bias applier 290 may be disposed in the chamber 215. According to an example embodiment, the bias applier 290 may include a first plate 270, a second plate 275, a ground device 280, and a power source 285. The first plate 270 may be disposed over the substrate 240, and the second plate 275 may be disposed under the substrate 240 to face the first plate 270. The ground device 280 may be connected to the first plate 270 using a line 271, and the power source 285 may be connected to the second plate 275 using a line 276. Alternatively, the ground device 280 may be connected to the second plate 275 using the line 276, and the power source 285 may be connected to the first plate 270 using the line 271. The substrate 240 may be disposed on a surface of the second plate 275 that faces the first plate 270, and a recess in which the substrate 240 is mounted may be formed in the second plate 275.

The first plate 270 may be grounded by the ground device 280, and the second plate 275 may apply an alternating current (AC) voltage or a direct current (DC) voltage from the power source 285 to a bottom of the substrate 240. Thus, an electric field may be generated between the first plate 270 and the substrate 240. For example, the first and second plates 270 and 275 may be formed of a conductive material, such as a metal. The size of each of the first and second plates 270 and 275 may be larger than that of the substrate 240 and the size may be controlled according to the purpose of deposition. For example, a voltage applied from the power source 285 to the bottom of the substrate 240 may range from +1000 to −1000V and be a direct current (DC) voltage, an alternating current (AC) voltage with a frequency of 0.01 Hz to 10 kHz, or a DC pulse voltage.

The bias applier 290 may guide the charged crystalline nanoparticles formed by dissociating a gas including an element of the crystalline thin film, toward the substrate 240 in the chamber 215. In this case, the charged crystalline nanoparticles may reach the substrate 240 at a relatively high flux. As a result, adhesion of the thin film formed from the charged crystalline nanoparticles to the substrate 240 may be improved, and the deposition rate of the thin film may be increased. In addition, the crystallinity of the deposited thin film may be increased. For example, when an AC voltage or a DC pulse voltage is applied, damage of the substrate 240 caused by the charged crystalline nanoparticles provided on the substrate 240 can be reduced. The above-described construction of the bias applier 290 may be applied to the bias applier 190 described in the first example embodiment with reference to FIG. 1.

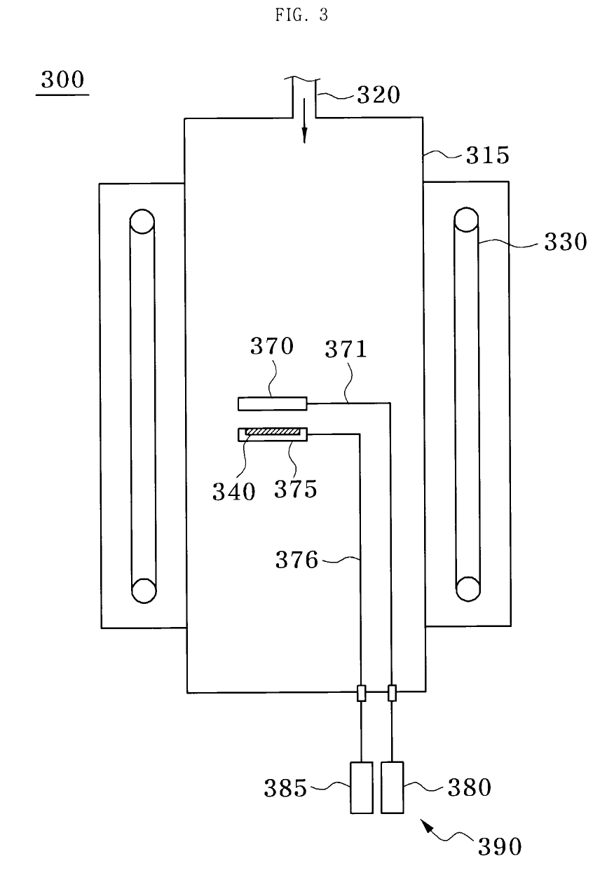

FIG. 3 is a schematic view of a thin film deposition apparatus according to a third example embodiment of the present disclosure.

Referring to FIG. 3 a thin film deposition apparatus 300 according to the third example embodiment of the present disclosure includes a chamber 315 into which a substrate 340 is loaded, a gas supplier 320, and an energy source 330. The thin film deposition apparatus 300 may further include a base applier 390 for generating an electric field in the substrate 340.

As shown in FIG. 3, the thin film deposition apparatus 300 may be provided in the form of a vertical furnace and may have about the same construction as the thin film deposition apparatus 200 described with reference to FIG. 2, except that a gas is vertically supplied to and exhausted from the chamber 315. Accordingly, a description of the same components as in the thin film deposition apparatus 200 will be omitted for brevity.

According to an example embodiment, charged crystalline nanoparticles may move downward due to the flow of a gas and contact a first plate 370. Thus, the first plate 370 may form a mesh so that the charged crystalline nanoparticles can pass through the first plate 370. The size, shape, and position of the mesh may be changed according to the purpose of deposition. The above-described construction of the bias applier 390 may be applied to the bias applier 190 described in the first example embodiment with reference to FIG. 1.

The thin film deposition apparatuses 100, 200, and 300 are described above with reference to FIGS. 1 through 3 as examples of the thin film deposition apparatus according to the example embodiments of the present disclosure. However, a thin film deposition apparatus according to an example embodiment is not limited thereto and various other changes may be made as known to those skilled in the art. For example, a plasma-enhanced vapor deposition process or a physical vapor deposition (PVD) process may be used.

Hereinafter, a method of depositing a thin film according to an example embodiment of the present disclosure will be described based on “the theory of a thin film deposition mechanism due to charged nanoparticles (hereinafter, the theory of charged nanoparticles)”. According to the theory of charged nanoparticles, reaction gases are dissociated in a vapor phase during a chemical deposition process to generate electrically charged nanoparticles, and the nanoparticles are deposited on a substrate to grow a thin film. The theory of charged nanoparticles has been disclosed in J. Crystal Growth 206 (1999) 177-186 by Nong M. Hwang et al; J. Crystal Growth 204 (1999) 85-90 by Nong M. Hwang; J. Crystal Growth 205 (1999) 59-63 by Nong M. Hwang; J. Crystal Growth 198/199 (1999) 945-950 by Nong M. Hwang; Int. Mat. Rev. 49 (2004) 49 171-190 by Nong-Moon Hwang et al; J. Ceramic Processing Res. 1 (2000) 34-44 by Nong-M. Hwang et al; J. Crystal Growth 218 (2000) 33-39 by Nong M. Hwang et al; J. Crystal Growth 218 (2000) 40-44 by Nong M. Hwang et al; J. Crystal Growth 213 (2000) 79-82 by Jn.-D. Jeon et al; J. Crystal Growth 204 (1999) 52-61 by Woo S. Cheong et al; J. Crystal Growth 242 (2002) 463-470 by S.-C. Lee; Pure Appl. Chem., vol. 78 (2006) 1715-1722 by Jin-Yong Kim et al; and Thin Solid Films 515 (2007) 7446-7450 by Jean-Ho Song et al.

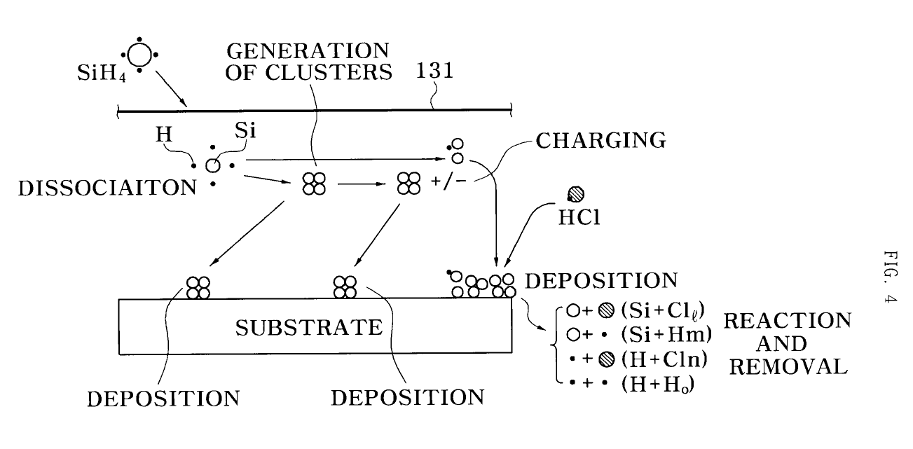

FIG. 4 is a conceptual diagram of a thin film deposition mechanism according to an example embodiment of the present disclosure. Although FIG. 4 illustrates a deposition mechanism of a crystalline Si film according to an example embodiment of the present disclosure, the deposition mechanism may be applied in substantially the same manner to form other kinds of crystalline films.

Referring to FIG. 4, initially, silane (SiH₄) gas is supplied into a chamber as a first reaction gas. The SiH₄ gas may be dissociated into Si and hydrogen (H₂) in a vapor phase due to heat generated by a hot-wire structure 131. When the dissociated vapor-phase Si is supersaturated in the chamber, Si may be precipitated. The precipitated Si may be nucleated and grown, thereby forming Si nanoparticles in a vapor phase. The Si nanoparticles formed in the vapor phase may contact a wall of the chamber or the surfaces of other particles, exchange internal charges, and be electrically charged. The Si nanoparticles in the vapor phase may easily grow into crystalline nanoparticles at a high temperature. The crystalline Si nanoparticles may be deposited on a substrate in a crystalline phase. The crystalline Si nanoparticles may function as seeds required for forming a crystalline thin film. Also, since the crystalline Si nanoparticles are charged, an electrical interaction may occur between the crystalline Si nanoparticles or between the crystalline nanoparticles and a grown surface. Consequently, the crystalline Si nanoparticles may be regularly oriented and deposited on the surface of the substrate. The crystalline Si nanoparticles may be sequentially deposited on the substrate, thereby forming a crystalline Si thin film on the substrate.

At least while the crystalline Si nanoparticles are being deposited on the substrate, HCl gas as an example of a second reaction gas may be supplied to the substrate. The HCl gas may react with an amorphous material formed on the substrate, for example, amorphous Si (a-Si) to produce Si+Clₗ and Si+Hₘ (here, each of l and m is an arbitrary integer), thereby removing or etching a-Si from the substrate. The a-Si may be formed on the substrate when a reaction group of a gas containing Si atoms that is not used to form the crystalline Si nanoparticles reacts with the substrate in the chamber. The a-Si may remain in a monatomic state or a cluster state close to the monatomic state, as compared with the crystalline nanoparticles obtained by combining Si atoms. Thus, the a-Si may be more reactive than the crystalline nanoparticles. Accordingly, the HCl may react with the a-Si earlier than the crystalline nanoparticles, thereby removing the a-Si from the substrate.

As a result, by use of the deposition mechanism based on the theory of charged nanoparticles, the crystalline thin film may be formed on the substrate. Since the crystalline Si nanoparticles are formed in a vapor phase, the substrate may be maintained at a relatively low temperature. Accordingly, a low-temperature substrate, such as a glass substrate or a polymer substrate, may be adopted.

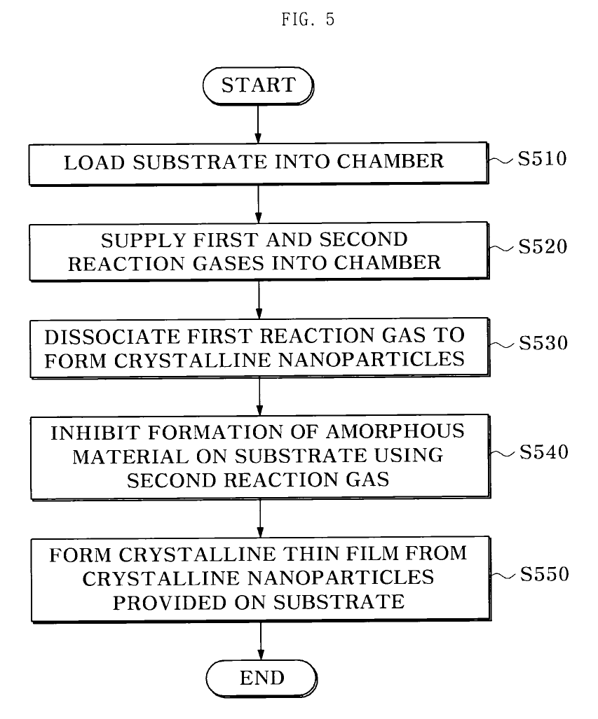

FIG. 5 is a flowchart illustrating a method of manufacturing a thin film according to an example embodiment of the present disclosure. Referring to FIG. 5, in step S510, a substrate is loaded into a chamber. The substrate may be formed of one selected from the group consisting of a conductive material, a nonconductive material, and a polymer. For instance, the substrate S may be a metal substrate, a polymer substrate, or a metal oxide substrate.

In step S520, a first reaction gas and a second reaction gas may be supplied into the chamber. According to an example embodiment, the first reaction gas may contain an element of a thin film that is substantially formed on the substrate. The first reaction gas may be supplied in a gaseous phase or a vapor phase into the chamber. The vapor-phase first reaction gas may be obtained by evaporating a liquid source.

According to an example embodiment, when a Si thin film is formed, the first reaction gas may include a silane-based compound denoted by SiₙH₂ₙ₊₂ (here, n is a natural number). For example, the first reaction gas may contain monosilane, disilane, trisilane, or tetrasilane. Specifically, the first reaction gas may contain monosilane, disilane, trisilane, or a gas mixture thereof. According to another example embodiment, the first reaction gas may include fluorosilane, an organic silane, or a compound or mixture thereof. The fluorosilane may be denoted by SiₙH₂ₙ₊₂₋ₘFₘ (here, each of n and m is a natural number, m<2n+2, and m may include 0). For example, the fluorosilane may be SiH₃F, SiH₂F₂, SiHF₃, SiF₄, Si₂F₆, Si₂HF₅, Si₃F₈. The organic silane may be denoted by SiₙR₂ₙ₊₂₋ₘHₘ. For example, the organic silane may be Si(CH₃)H₃, Si(CH₃)₂H₂, or Si(CH₃)₃H.

According to an example embodiment, when a germanium (Ge) thin film is formed, the first reaction gas may be a Ge gas, a germanium fluoride gas, or a compound or mixture thereof. The Ge gas may be denoted by GeₙH₂ₙ₊₂ and be, for example, GeH₄ or Ge₂H₆. The germanium fluoride gas may be denoted by GeₙH₂ₙ₊₂₋ₘFₘ and be, for example, GeF₄.

According to an example embodiment, when a carbon thin film, a carbon nanotube, or a carbon nanowire is deposited, the first reaction gas may include a hydrocarbon gas or other hydrocarbon compounds. The hydrocarbon gas may be, for example, CH₄, C₂H₆, C₃H₈, C₂H₄, or C₂H₂.

Although each of the above-described examples of the first reaction gas may be used alone, an additional gas may be used along with the first reaction gas. The additional gas may be: a reactive gas, such as a fluorine (F) gas or a chlorine (Cl) gas; a gas containing a Group III element as a dopant, such as B₂H₆ or B(CH₃)₃; a gas containing a Group V element as a dopant, such as PH₃; an inert gas, such as He gas, Ar gas, or Ne gas; or H₂ gas or N₂ gas.

The second reaction gas may include a compound gas containing a Group 17 element, such as HCl. The second reaction gas may include a highly reactive element, such as Cl or F. According to an example embodiment, although each of the above-described examples of the second reaction gas may be used alone, an additional gas may be used along with the second reaction gas. The additional gas may be: a gas containing a Group III element as a dopant, such as B₂H₆ and B(CH₃)₃; a gas containing a Group V element as a dopant, such as PH₃; an inert gas, such as He gas, Ar gas, and Ne gas; or H₂ gas or N₂ gas.

In step S530, the first reaction gas may be dissociated to form crystalline nanoparticles. The first reaction gas may be dissociated in the chamber due to an energy source, thereby forming the crystalline nanoparticles in a vapor phase.

According to an example embodiment, the energy source may apply heat or plasma to dissociate the first reaction gas. According to an example embodiment, the crystalline nanoparticles may be positive-charged or negative-charged according to the types of the crystalline nanoparticles. In other words, the charged state of the crystalline nanoparticles may be varied according to process conditions, i.e., the internal pressure or temperature of the chamber in which the crystalline nanoparticles are formed. As another example, the charged state of the crystalline nanoparticles may be varied according to the kind and chemical components of the hot-wire structure (refer to 131 in FIG. 1), which is an example of the energy source.

According to an example embodiment, an electric field may be generated in the substrate so that the charged crystalline nanoparticles may be guided to the substrate.

In step S540, formation of an amorphous material on the substrate may be inhibited using the second reaction gas. In other words, the second reaction gas may be used to inhibit the amorphous material from growing on the substrate or to etch the already grown amorphous material. The amorphous material may contain the same element as that of a crystalline thin film to be formed on the substrate.

According to an example embodiment, HCl gas, as an example of the second reaction gas, may react with a-Si, which may be formed on the substrate to produce Si+Clₗ and Si+Hₘ (here, each of l and m is an arbitrary integer), thereby removing or etching a-Si from the substrate.

In addition, the HCl gas may react with hydrogen bonded to the a-Si, thereby removing the hydrogen from the substrate. Specifically, Cl or H dissociated from the HCl gas may react with the hydrogen bonded to the a-Si to produce H+Clₙ, H+Hₒ(here, each of n and o is an arbitrary integer), thereby removing the hydrogen from the substrate.

In step S550, a crystalline thin film may be formed from the crystalline nanoparticles provided on the substrate. The crystalline nanoparticles formed on the substrate may function as seeds used for forming a crystalline thin film. Also, since the crystalline nanoparticles are charged, an electrical interaction may be caused between the crystalline nanoparticles or between the crystalline nanoparticles and a grown surface, so that the crystalline nanoparticles can be regularly oriented and deposited on the surface of the substrate, thereby forming a crystalline thin film on the substrate. For example, the crystalline thin film may include a Si film, a silicon nitride (SiN) film, a Ge film, a carbon thin film, a carbon nanotube, or a carbon nanowire.

According to an example embodiment, steps S400 and S500 may be performed at the same time or step S400 may be performed at least during step S500.

According to an example embodiment, the crystallinity of the crystalline thin film formed on the substrate may be controlled by adjusting a ratio of the first reaction gas to the second reaction gas.

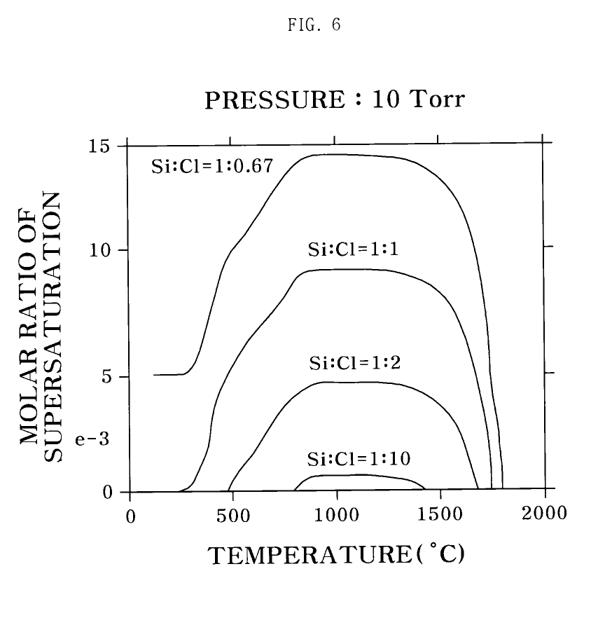

FIG. 6 is a graph of simulation results showing supersaturation of Si in a Cl-containing atmosphere. Specifically, FIG. 6 shows a molar ratio of supersaturated Si in a vapor phase according to an internal temperature of the chamber and a ratio of Si to Cl in a vapor phase in a chamber with maintaining a entire pressure of 10 Torr.

Referring to FIG. 6, it can be observed that as the ratio of Cl to Si in the vapor phase increases, the molar ratio of the supersaturated Si decreases over the entire temperature range. Also, it can be seen that when the ratio of Si to Cl is constant, as a temperature increases, the molar ratio of saturated Si increases and then decreases again. As described above, crystalline Si nanoparticles may be obtained by nucleating and growing the supersaturated Si in the vapor phase. Accordingly, when the ratio of Si to Cl is constant, it can be estimated that the crystalline Si nanoparticles are formed at a high temperature of about 1000 to 1500° C., and the amount of the formed crystalline Si nanoparticles is sharply reduced at a temperature of less than about 1000° C. Similarly, in the thin film deposition apparatus 100 described with reference to FIG. 1, the crystalline nanoparticles may be formed using the first reaction gas in high-temperature regions around the hot-wire structure 131, while formation of the crystalline Si nanoparticles using the first reaction gas is inhibited in low-temperature regions around the substrate S.

According to the above-described method of manufacturing a thin film, the first reaction gas may be dissociated to form the crystalline nanoparticles, and the crystalline thin film may be formed from the crystalline nanoparticles provided on the substrate. In this case, the second reaction gas may prevent clusters of an amorphous element dissociated from the first reaction gas from being formed on the substrate. Accordingly, the crystallinity of the crystalline thin film formed on the substrate can be improved. In this method, a high-quality crystalline thin film may be formed at a low temperature without additionally performing conventional post-annealing and dehydrogenation processes after depositing the crystalline thin film. In addition, a process time and production costs can be reduced by omitting the post-annealing and dehydrogenation processes. Furthermore, the crystallinity, deposited thickness, and surface state of a thin film may be controlled at a user' s request.

Moreover, since a high-quality crystalline thin film may be easily manufactured at a low temperature, the crystalline thin film may be applied to various electronic devices, for example, display devices, such as organic light emitting diode (OLED) display devices and flexible display devices, and solar batteries.

Hereinafter, an experimental example according to the present disclosure will be described.

### EXPERIMENTAL EXAMPLE

A Si thin film was formed on a substrate using the thin film deposition apparatus described with reference to FIG. 1. Silane gas as s a first reaction gas was supplied at a concentration of 10% and a flow rate of 100 sccm, and a filament-type hot-wire structure was used. The hot-wire structure was heated to a temperature of about 1600° C. to dissociate the first reaction gas.

HCl gas with a purity of 99.9% as a second reaction gas was supplied at the same time as the first reaction gas while varying the flow rate of the HCl gas as shown in Table 1, thereby depositing thin films. In the case of (a) in which the HCl gas was not used, a conventional thin film according to a comparative example was obtained.

The substrate was a Corning glass substrate that was 2.5 cm wide, 2.5 cm long, and 1 mm thick. The substrate was maintained at a temperature of about 320° C., and a bias voltage was applied to the substrate. The inside of a chamber was maintained under a pressure of about 10 Torr, and a process time was 20 minutes.

TABLE 1

| | (a) | (b) | (c) | (d) |
|---|---|---|---|---|
| Flow rate of HCl | 0 | 10 | 16 | 28 |

The crystallinity of each of the thin films deposited at various flow rates of HCl was measured using a Raman spectrometer.

[Analysis]

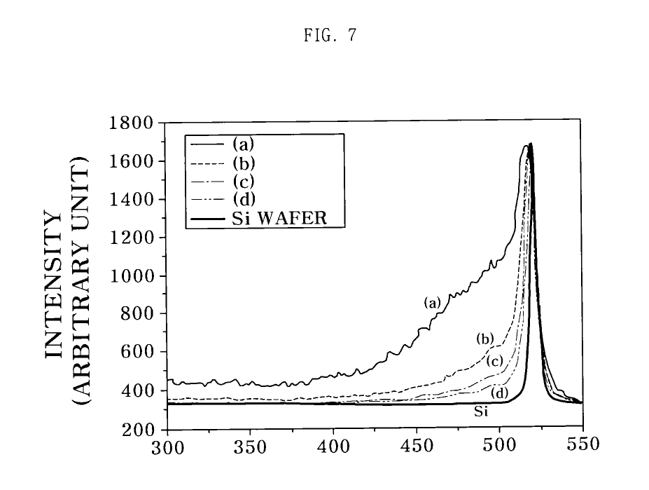

FIG. 7 is a graph of measurement results of the thin films deposited according to the flow rate of HCl, which are obtained using a Raman spectrometer, according to an example embodiment of the present disclosure.

Referring to FIG. 7, in the case of Comparative example (a), it can be observed that a-Si was dominant in the deposited thin film. Also, as the flow rate of HCl gas increased, peaks of curves became nearer to the peak of crystalline Si in a Si wafer. Accordingly, it can be seen that as the flow rate of HCl gas increased, the crystallinity of the thin film also increased. Therefore, it can be concluded that when HCl gas was supplied at a higher flow rate, a-Si could be removed from the substrate more effectively to reduce the amount of a-Si contained in the thin film.

While the disclosure has been shown and described with reference to m certain example embodiments thereof, it will be understood by those skilled in the art that various changes in form and details may be made therein without departing from the spirit and scope of the disclosure as defined by the appended claims.

1. A method of manufacturing a thin film, comprising:
(a) loading a substrate into a chamber;
(b) supplying a first reaction gas and a second reaction gas into the chamber;
(c) dissociating the first reaction gas to form crystalline nanoparticles;
(d) inhibiting an amorphous material from being formed on the substrate using the second reaction gas; and
(e) forming a crystalline thin film from the crystalline nanoparticles provided on the substrate.

2. The method according to claim 1, wherein in step (c), the crystalline nanoparticles are negative-charged or positive-charged depending on the types of the crystalline nanoparticles.

3. The method according to claim 2, wherein the charged state of the crystalline nanoparticles is varied according to an internal pressure or temperature of the chamber in which the crystalline nanoparticles are formed.

4. The method according to claim 1, wherein the first reaction gas comprises an element of the crystalline thin film.

5. The method according to claim 4, wherein the first reaction gas comprises at least one selected from the group consisting of a silane-based compound, a germanium-based compound, and a hydrocarbon-based compound.

6. The method according to claim 1, wherein step (c) comprises dissociating the first reaction gas using heating or plasma to form the crystalline nanoparticles in a vapor phase.

7. The method according to claim 2, further comprising (f) generating an electric field in the substrate to guide the charged crystalline nanoparticles to the substrate.

8. The method according to claim 1, wherein step (d) comprises inhibiting the amorphous material from growing on the substrate using the second reaction gas or etching an already grown amorphous material using the second reaction gas.

9. The method according to claim 8, wherein the amorphous material comprises the same element as that of the crystalline thin film.

10. The method according to claim 1, wherein the second reaction gas comprises a Group 17 element.

11. The method according to claim 10, wherein the second reaction gas comprises a fluoride-based compound or a chloride-based compound.

12. The method according to claim 1, wherein the crystallinity of the crystalline thin film is determined by a mixture ratio of the first reaction gas and the second reaction gas that are supplied.

13. The method according to claim 1, wherein the amount of the formed crystalline nanoparticles is proportional to the supersaturation in a vapor phase according to a temperature of an element dissociated from the first reaction gas.

14. The method according to claim 1, wherein the crystalline thin film comprises one selected from the group consisting of a silicon film, a silicon nitride film, a germanium film, a carbon thin film, a carbon nanotube, and a carbon nanowire.

15. The method according to claim 1, wherein steps (d) and (e) are performed at the same time.

16. An apparatus for manufacturing a thin film, comprising:
a chamber into which a substrate is loaded;
a first gas supplier configured to supply a first reaction gas into the chamber;
an energy source configured to dissociate the first reaction gas to form crystalline nanoparticles; and
a second gas supplier configured to supply a second reaction gas used to inhibit an amorphous material from being formed on the substrate.

17. The apparatus according to claim 16, wherein the energy source comprises a hot-wire structure installed between the first gas supplier and the substrate.

18. The apparatus according to claim 16, further comprising a substrate shield installed over the substrate to be capable of being opened and closed and configured to shield the substrate from the first reaction gas or heat emitted by the energy source.

19. The apparatus according to claim 16, further comprising a bias applier connected to the substrate and configured to generate an electric field in the substrate.

20. The apparatus according to claim 19, wherein the bias applier includes:
a first plate installed over the substrate;
a second plate installed under the substrate to face the first plate;
a power source configured to apply a voltage to one of the first and second plates; and
a ground device configured to ground the other of the first and second plates.

21. The apparatus according to claim 20, wherein the voltage is one selected from the group consisting of an alternating current (AC) voltage, a direct current (DC) voltage, and a DC pulse voltage.

22. The apparatus according to claim 20, wherein the substrate is disposed on a surface of the second plate that faces the first plate, the ground device is connected to the first plate, and the power source is connected to the second plate.
